(19) United States
(12) Patent Application Publication
(10) Pub. No.: US 2017/0197343 A1
(43) Pub. Date: Jul. 13, 2017

(54) METHOD AND APPARATUS FOR PROVIDING REINFORCED COMPOSITE MATERIALS WITH EMI SHIELDING

(71) Applicant: Edward J. Wenzel, Troy, MI (US)

(72) Inventor: Edward J. Wenzel, Troy, MI (US)

(21) Appl. No.: 15/411,440

(22) Filed: Jan. 20, 2017

Related U.S. Application Data
(62) Division of application No. 13/267,403, filed on Oct. 6, 2011.
(60) Provisional application No. 61/390,410, filed on Oct. 6, 2010.

(51) Int. Cl. B29C 43/34; H05K 9/00

(52) U.S. Cl. CPC B29C 43/34; H05K 9/0083; H05K 9/009

(57) ABSTRACT

A method of forming an item with electromagnetic interference shielding, the method including the steps of: inserting a first polymer into a first compounding extruder, wherein the first compounding extruder provides a first melted charge; inserting the first melted charge into a second compounding extruder, wherein the second compounding extruder introduces a plurality of conductive fibers into the first melted charge and wherein the second compounding extruder provides a second melted charge comprising the first melted charge and a plurality of conductive fibers; depositing the second melted charge onto a least one die of a compression mold; and closing the compression mold about the second melted charge in order to form the item.

### CROSS REFERENCE TO RELATED APPLICATIONS

This application is a divisional of U.S. patent application Ser. No. 13/267,403 filed Oct. 6, 2011, which claims the benefit of U.S. Provisional Patent Application No. 61/390,410 filed Oct. 6, 2010, the entire contents of each of these applications are incorporated herein by reference thereto.

### TECHNICAL FIELD

Exemplary embodiments of the present invention relate generally to composite materials and methods of making composite materials with specific characteristics. Still further, exemplary embodiments of the present invention also generally relate to the manufacture of fiber-reinforced thermoplastic polymeric structural components and, more particularly, to an apparatus and method for, in-line compounding, deposition and compression molding of thermoplastic polymeric structural components.

### BACKGROUND

Typical electromagnetic interference (EMI) shielding enclosures consist of either metal or a highly filled polymer composite. A conductive medium is required in order to shield both the contents of the enclosure as well as components surrounding the enclosure from stray electromagnetic fields. Common metal enclosures include steel and aluminum. Polymer composites are commonly injection molded thermoplastics containing stainless steel fibers, carbon fibers and/or nickel coated carbon fibers.

Metal enclosures can be formed by bending and welding sheet-metal or casting aluminum and impregnating with a binder to seal any porosity. Formed sheet metal enclosures generally are limited in terms of contour and feature.

Accordingly, it is desirable to provide a composite having EMI shielding as well as an apparatus for providing such a composite. Still further is also desirable to provide a component formed from the composite having EMI shielding. In addition is also desirable to form this component from an extrusion compression molding process.

### SUMMARY OF THE INVENTION

In accordance with an exemplary embodiment a method of producing an electrical enclosure out of polymer composites using an alternative molding technology as well as conductive nano-sized filler technology.

According to an exemplary embodiment of the present invention, a method of forming an item with electromagnetic interference shielding, the method including the steps of: inserting a first polymer into a first compounding extruder, wherein the first compounding extruder provides a first melted charge; inserting the first melted charge into a second compounding extruder, wherein the second compounding extruder introduces a plurality of conductive fibers into the first melted charge and wherein the second compounding extruder provides a second melted charge comprising the first melted charge and the plurality of conductive fibers; depositing the second melted charge onto a least one die of a compression mold or onto a conveyor for subsequent transfer onto a die of a compression mold; and closing the compression mold about the second melted charge in order to form the item.

In another exemplary embodiment, an extrusion compression molding assembly is provided, the assembly having: a first polymer compounding extruder; a second polymer compounding extruder configured to receive a melted charge from the first polymer compounding extruder; and an assembly for providing a plurality of fibers into the second polymer compounding extruder, wherein the assembly and the second polymer compounding extruder provide a fiber reinforced melt charge having conductive qualities.

The above-described and other features and advantages of the present invention will be appreciated and understood by those skilled in the art from the following detailed description, drawings, and appended claims.

### BRIEF DESCRIPTION OF THE DRAWINGS

Embodiments of the present invention will now be described, by way of example only, with reference to the accompanying drawings in which:

FIG. 1 is a schematic illustration of an extrusion compression molding (ECM) cell in accordance with an exemplary embodiment of the present invention; and

FIG. 2 illustrates one non-limiting method of forming an item with EMI shielding in accordance with an exemplary embodiment of the present invention.

### DETAILED DESCRIPTION

An in-line compounding and extrusion compression molding apparatus for producing a fiber-reinforced molded structural component with EMI shielding is provided. The apparatus allows for forming a first polymer melt, supplying the first polymer melt to a second extruder that compounds the polymer melt with at least one reinforcing fiber to form a fiber-reinforced polymer compound, depositing the fiber-reinforced polymer compound onto a compression mold, and molding the reinforced structural component therein.

Reference is made to the following U.S. Pat. Nos. 6,648,402, 6,558,146, 6,508,967, and 6,497,775, the contents each of which are incorporated herein by reference thereto.

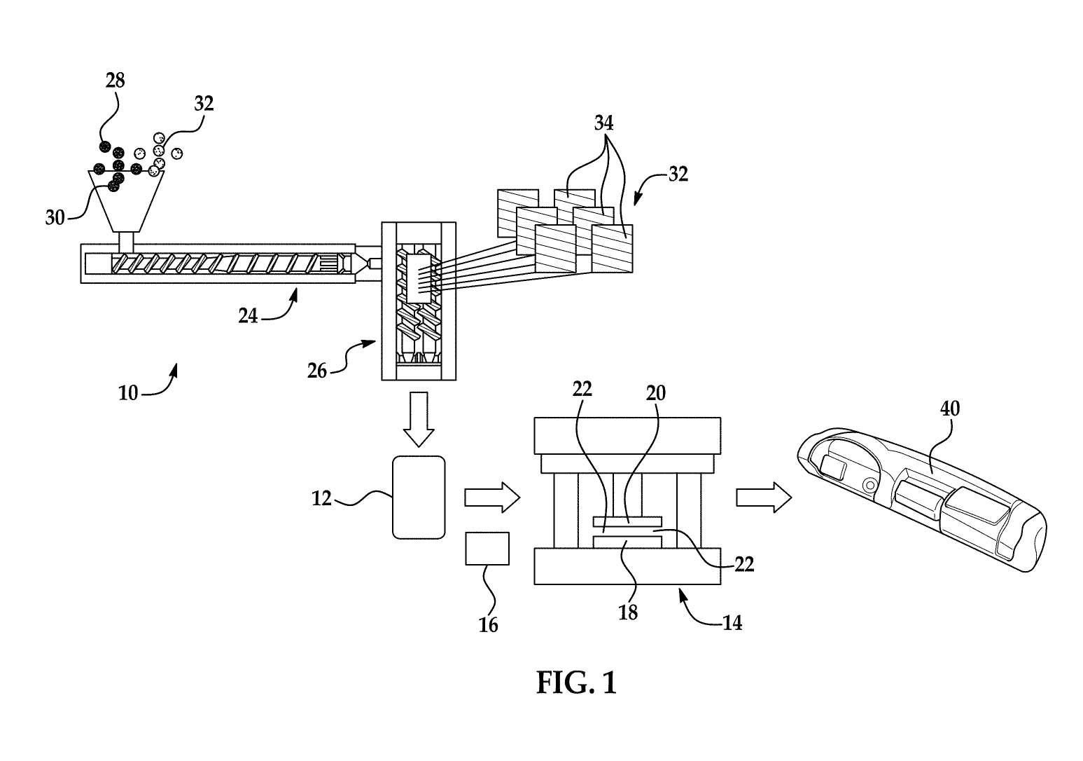

FIG. 1 depicts an exemplary embodiment of an extrusion compression molding (ECM) cell 10 in accordance with an exemplary embodiment of the present invention. ECM is an open mold process, and this feature allows for the use of specific processing techniques to combine different polymer materials and/or inserts within the same tool or mold cavity. The ECM cell 10 produces a melt charge 12 that is ultimately provided to a compression mold 14 located within a vertical compression press 15 by a robot or other equivalent device 16. The compression mold will have a female half 18 and a male half 20, each including a contact surface 22. The female and male halves are complimentary in shape to mate with each other. The compression mold may also be a conventional mold generally used for molding polymers to desired shapes and forms.

In one embodiment, the compounding extruders 24, 26 are disposed movably on a 3-axis table (not shown) so that the melt charge can be deposited directly onto the contact surfaces or alternatively the robot may move to transfer the melt charge from a melt take-up conveyor (not shown) with respect to a fixed mold.

The ECM assembly 10 further includes a first polymer compounding extruder 24 that feeds a melted charge to a second fiber/polymer mixing extruder 26. Each extruder is a twin screw extruder having a body, an inlet end and an outlet end with a die. The screws rotate to mix and move a polymer melt towards the outlet end of the extruder.

The polymer melt of the first compounding extruder 24 is formed from a polymer material 28 that is introduced into the first extruder by any number of techniques including the use of a hopper 30 into which the polymer material is fed. Often, the polymer material is in the form of plastic pellets. Still further and as an alternative additives 32 may be added to the hopper 30. In one embodiment, the additives include coupling agents, heat stabilizers, colorants, regrind material, and other fillers to enhance mechanical properties. Alternatively, the additives may be included in the polymer material of pellets 28 or alternatively a polymer material may be applied without any additives and the additives are included with the second extrusion deposition compounding device. Still further and in one embodiment, the additives or at least some of the additives are electrically conductive or have conductive characteristics such that an item formed from the polymer material will be integrally formed with EMI shielding capabilities. Non-limiting examples of such conductive additives are selected from the group consisting of glass, carbon, stainless steel, conductive nano-sized filler technology, nano wires, equivalents thereof and combinations thereof. Still further the aforementioned additives may be supplied in a fiber configuration.

The second compounding extruder 26 also has an inlet end and an outlet end. The outlet end further includes a deposition die head 30 for forming/shaping the fiber-reinforced melt charge.

The second compounding extruder also includes a fiber feeding apparatus 33. The fiber feeding apparatus provides a means of introducing continuous fiber to the second compounding extruder and includes a fiber supply reel or a plurality of fiber supply reels 34 each containing at least one fiber wound thereabout at a predetermined tension. The at least one fiber may be glass, carbon, stainless steel, etc. Still further and in one embodiment, the fibers or at least some of the fibers are electrically conductive or have conductive characteristics such that an item formed from the polymer material will be integrally formed with EMI shielding capabilities. Non-limiting examples of such conductive fibers may be selected from the aforementioned group consisting of glass, carbon, stainless steel, conductive nano-sized filler technology, nano wires, equivalents thereof and combinations thereof.

Alternative means of feeding fiber into the second compounding extruder includes, but is not limited to, loss—in-weight feeders for feeding discontinuous (chopped) fiber into the extruder feedthroat as well as in-line fiber chopping equipment for cutting and feeding continuous fiber that cannot easily be cut within the extruder barrel. Alternatively, the fiber is of a configuration that is chopped within the screws of the extruder barrel.

The fibers are introduced into the second compounding extruder to provide a desired reinforcement application as well as the EMI shield capabilities of the formed item.

The second compounding extruder further includes a severing assembly having a cutting member and an actuator wherein activation of the actuator causes movement of the cutting member to cut the melt into charges 12 onto a conveyor belt (not shown) so that the robot or other equivalent device 16 can pick up the melt charge and deposit it on one of the halves of the compression mold. Thereafter, the compression mold forms an item 40 constructed out of the composite material having EMI shielding characteristics. Since item 40 is formed from a molding process it can have almost any configuration while still having EMI shielding characteristics. One non-limiting configuration of item 40 is an instrument panel or interior portion of a vehicle.

Each extruder will include a heating element that, along with shear and pressure, plasticates the polymer composite melt which ultimately comprises the melt charge that is disposed onto the dies of the compression mold 14. The heating elements (not shown) in combination with the shear heat introduced by the rotation of the screws of the extruders form the polymer melt. In addition, the percentage of reinforcing fibers and/or conductive fibers in the resulting compound may be varied by controlling the number of fibers provided by the fiber feeding apparatus. Thus, the percentage of the reinforcing fibers and/or conductive fibers may be varied by increasing or decreasing the amount of reinforcing fibers compounded with the polymer melt. Reinforcing fibers/fillers may be added to either or both compounding extruders in various percentages simultaneously to provide a polymer composite with optimized mechanical properties and lowest cost.

Use of extrusion compression molding with an in-line material compounding (ECM w/ILC or LFT-D-ILC compression) process technology enables the production of a custom formulated composite for EMI shielding, mechanical performance, and fire retardancy as required while providing a high performance/cost ratio.

As such, a method and apparatus for providing an item formed with EMI shielding capabilities is provided wherein electrically conductive additives are provided into either the first extruder or the second extruder or alternatively both the first and second extruders or any combination thereof such that the resulting melt charges include electrically conductive materials and items formed therefrom are provided with EMI shielding characteristics.

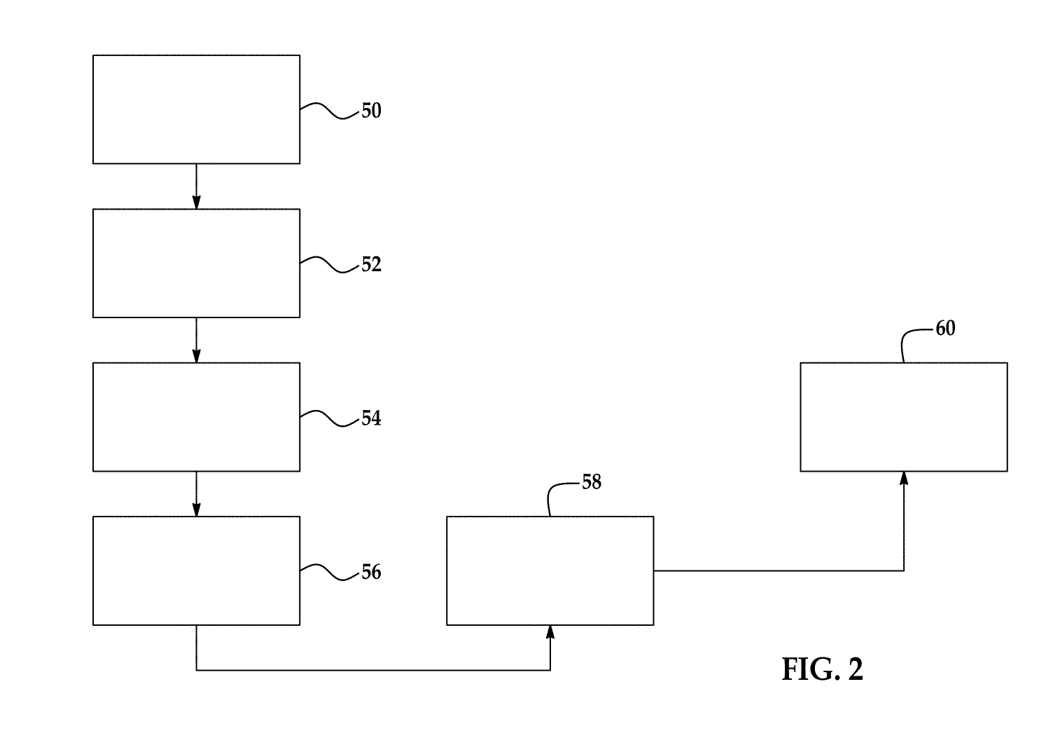

FIG. 2 illustrates at least one non-limiting method of forming an item with electromagnetic interference shielding in accordance with an exemplary embodiment of the present invention. In a first step 50, a first polymer is inserted into a first compounding extruder, wherein the first compounding extruder provides a first melted charge. At a second step 52, the first melted charge is extruded into a second compounding extruder, wherein the second compounding extruder introduces a plurality of electrically conductive fibers at step 54 into the first melted charge and wherein the second compounding extruder provides a second melted charge at step 56 comprising the first melted charge and the plurality of conductive fibers. Thereafter and at step 58, the second melted charge is deposited onto a least one die of a compression mold. At step 60, the compression mold is closed about the second melted charge in order to form the item with EMI shielding capabilities since electrically conductive items are introduced to the melted charge. In an alternative embodiment and as mentioned above, electrically conductive additives at added at step 50 or at least some of the additives added at step 50 are electrically conductive or have conductive characteristics such that an item formed from the polymer material will be integrally formed with EMI shielding capabilities. These electrically conductive additives may be in lieu of or in addition to the plurality of electrically conductive fibers added at step 54.

While the invention has been described with reference to an exemplary embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. An extrusion compression molding cell, comprising:
a first polymer compounding extruder;
a second polymer compounding extruder configured to receive a melted charge from the first polymer compounding extruder; and
a fiber feeding apparatus for providing a plurality of fibers into the second polymer compounding extruder, wherein the first polymer compounding extruder and the second polymer compounding extruder provide a fiber reinforced melt charge having conductive qualities.

2. The extrusion compression molding cell as in claim 1, further comprising: a compression mold configured to receive the fiber reinforced melt charge.

3. The extrusion compression molding cell as in claim 1, further comprising: a compression mold configured to receive the fiber reinforced melt charge.

4. The extrusion compression molding cell as in claim 1, wherein a plurality of additives are also inserted into the first compounding extruder.

5. The extrusion compression molding cell as in claim 4, wherein at least some of the plurality of additives have conductive characteristics that provide the item with an integral electromagnetic interference shielding.

6. The extrusion compression molding cell as in claim 5, wherein the plurality of additives that have conductive characteristics are selected from the group consisting of glass, carbon, stainless steel and combinations thereof.

7. The extrusion compression molding cell as in claim 1, wherein at least some of the plurality of fibers are conductive fibers selected from the group consisting of glass, carbon, stainless steel and combinations thereof and the conductive fibers provide the item with an integral electromagnetic interference shielding.

8. The extrusion compression molding cell as in claim 7, further comprising: a compression mold configured to receive the fiber reinforced melt charge, wherein the mold is configured to define an item for use as an interior component of a vehicle.

9. The extrusion compression molding cell as in claim 8, wherein the interior component is an instrument panel of a vehicle.
